(19) United States
(12) Patent Application Publication
(10) Pub. No.: US 2026/0262340 A1
(43) Pub. Date: Sep. 3, 2026

(54) LED CHIP ELECTRODE

(71) Applicant: GOLDEN SCORPION (AH) CO., LTD., Maanshan City (CN)

(72) Inventors: Shengmao MA, Maanshan City (CN); Shilong FENG, Maanshan City (CN); Lingsong E, Maanshan City (CN); Runzhang HONG, Maanshan City (CN); Jian GUO, Maanshan City (CN)

(21) Appl. No.: 19/576,254

(22) Filed: Mar. 24, 2026

(30) Foreign Application Priority Data
Dec. 24, 2025 (CN) 202511964507.3

(51) Int. Cl. H10H 20/831; H10H 20/832; H10H 20/857

(52) U.S. Cl. CPC H10H 20/831; H10H 20/832; H10H 20/857

(57) ABSTRACT

The present invention discloses an LED chip electrode, relating to the technical field of semiconductor photoelectric devices. The LED chip of the present invention includes a chip body, electrode pads disposed on the periphery of the chip body, and finger gold wire electrodes disposed on a surface of the chip body. Four or more electrode pads are provided, and are symmetrically and equally spaced apart along the periphery of the chip body. The finger gold wire electrodes are equally spaced apart, and a spacing between two adjacent ones of the finger gold wire electrodes is determined according to the following formula: Lₛ=n*sqrt(R_{c}/Rₛ), where Lₛ is the spacing between the finger gold wire electrodes, n is an electrode pad factor, R_{c} is a contact resistance between the finger gold wire electrodes and the chip body, and Rₛ is a sheet resistance of the chip body.

### TECHNICAL FIELD

The present invention relates to the technical field of semiconductor photoelectric devices, and in particular, to an LED chip electrode.

### BACKGROUND

With the rapid development of modern agrarian, the plant supplementary lighting technology has become a key support for improving the crop yield and quality, where an LED lamp is widely applied to the field of plant supplementary lighting by virtue of its advantages such as low energy consumption and strong spectrum tunability. In the scenario of plant supplementary lighting, the lighting effect of a lamp directly determines the supplementary lighting efficiency, while the lighting effect performance of an LED package, which serves as a core light emitting element of the lamp, is a determining factor for the lighting effect of the entire lamp. Moreover, a strict requirement is imposed onto the shaded area of the lamp in the industry, which also restricts the light emitting area of the LED package from being very large.

To adapt to the foregoing demand in the field of plant supplementary lighting, the industry has imposed a core performance requirement of “large current+high lighting effect” onto the LED package. Specifically, in terms of achieving a high light output in a limited light emitting area, increasing the operating current of the LED package from conventional 700 mA to 2000 mA theoretically can achieve a high light output. However, this imposes an extremely high requirement onto the design of a finger gold wire electrode on the surface of a chip of the LED package. As the current increases, the current of the chip of the LED package spreads unevenly. To solve this problem, a conventional solution involves increasing the number of finger gold wire electrodes or increasing the line width of the electrode. However, the increase in the number of electrodes or the increase in the line width necessarily increases the proportion of shading by the electrode on the surface of the chip. A larger area of the light emitting region of the chip that is shaded by the electrode results in a smaller effective region participating in light emitting. This directly causes significant degradation in the lighting effect of the package, which contradicts the core demand of a high lighting effect of the chip of the package. Finding a balance between the foregoing design indicators has currently become an insurmountable difficulty.

In addition, considering the operating conditions during actual use of a plant supplementary lighting lamp, it is usually also required to ensure that when used under a high-temperature operating condition of 85° C. or above, the LED package still has the indicator of a high lighting effect. Therefore, there is an urgent need to solve the foregoing problem in the industry, so as to achieve the indicator requirement that the package still has a high lighting effect under a large current+a high-temperature condition of 85° C. or above.

### SUMMARY

To solve the shortcomings mentioned in the foregoing background, the present invention provides an LED chip electrode. By adding electrode pads on the periphery of a chip in combination with improving the spacing between finger gold wire electrodes on the surface of the chip, the indicator requirement that a package still has a high lighting effect under a large current+a high-temperature condition of 85° C. or above is effectively achieved.

To achieve the foregoing objective, the present invention adopts the following technical solution:

The present invention provides an LED chip electrode, including a chip body, electrode pads disposed on the periphery of the chip body, and finger gold wire electrodes disposed on the surface of the chip body.

Four or more electrode pads are provided, and are symmetrically and equally spaced apart along the periphery of the chip body.

The finger gold wire electrodes are equally spaced apart, and the spacing between two adjacent ones of the finger gold wire electrodes is determined according to the following formula:

Lₛ=n*sqrt(R_{c}/Rₛ)

where Lₛ is the spacing between two adjacent ones of the finger gold wire electrodes, n is an electrode pad factor, which is specifically the number of the electrode pads, R_{c} is the contact resistance between the finger gold wire electrodes and the chip body, and Rₛ is the sheet resistance of the chip body.

It should be noted that one of core determining factors for the lighting effect of the package is the performance of the LED chip. Under a large current of 2000 mA+an extreme operating condition of a high temperature above 85° C., the design of the finger gold wire electrodes on the surface of the chip becomes a key bottleneck that restricts the maintenance of a high lighting effect of a lamp. Under this operating condition, extremely high requirements are imposed onto current carrying capability, heat dissipation performance, current spreading uniformity, and high-temperature aging resistance performance of the electrode, making it difficult to adapt to an existing electrode design solution. The existing design solution mainly has the following contradictions:

First, in a large-current design, a large-current conduction demand contradicts the current spreading uniformity. To carry a large current of 2000 mA, the conduction capability is improved by increasing the number of finger gold wire electrodes or increasing the line width of the electrode. This apparently causes a significant increase in the proportion of shading by the electrode in a light emitting region of the chip, and is likely to concentrate the current in a region near the electrode, causing a sparse current distribution in the light emitting region on the edge of the chip, which leads to a phenomenon of “overcurrent at the origin point and undercurrent on the edge”. This reduces the light emitting efficiency, and intensifies local heat generation on the chip due to a nonuniform current distribution, thereby further deteriorating lighting effect stability under the high-temperature operating condition.

Second, a high temperature above 85° C. accelerates aging of a contact interface between the finger gold wire electrode and the chip, causing an increase in the contact resistance, thereby generating additional Joule heat, and forming a local hot spot. A conventional bond structure between a gold wire and a chip is prone to thermal fatigue at a high temperature, causing a decrease in the bond strength and deterioration of conduction stability, resulting in sharp degradation of the lighting effect of the package and even a failure of the package. In addition, the existing electrode design lacks a heat dissipation path for the local hot spot, making it difficult to ensure a long-term high-lighting effect output of the package.

Third, the existing solution attempts to employ a high-conductivity alloy gold wire or a complex multi-layer electrode structure, so as to improve large-current carrying performance and high-temperature resistance performance. However, such solution greatly increases the cost of an electrode material and the difficulty in a manufacturing process, which contradicts the cost control demand of large-scale application of the plant supplementary lighting lamp. If the conventional low-cost gold wire electrode is used, the requirement of maintaining a high lighting effect under a large current+a high-temperature operating condition cannot be satisfied.

Therefore, under a large current of 2000 mA+a high-temperature operating condition above 85° C. faced by the plant supplementary lighting LED package, how to stably maintain a high lighting effect while controlling a chip manufacturing cost by optimizing the design of the finger gold wire electrode on the surface of the chip in combination with large current conduction, uniform current spreading, high-efficient heat dissipation, and high-temperature aging resistance performance has become a core technical problem under urgent need of solving by the present invention. Therefore, the present invention creatively involves adding the electrode pads on the periphery of the chip and optimizing the design of the distribution of the electrode pads, in combination with the improved spacing calculation formula for the finger gold wire electrodes on the surface of the chip, which further introduces the additional electrode pad factor, that is, the number of the electrode pads, to optimize the spacing between the finger gold wire electrodes. This effectively solves the design problem of the LED chip electrode under a large current of 2000 mA+a high-temperature operating condition above 85° C., significantly improving the lighting effect of the LED chip electrode, and effectively accelerating research and industrialization processes of a plant supplementary lighting LED package.

As a possible implementation of the present invention, the number of the electrode pads is four or six. A conventional chip electrode generally employs a single electrode pad or double electrode pads. The present invention involves increasing the electrode pads to four electrode pads or six electrode pads. However, just increasing the electrode pads also increases the shaded area of the chip. Therefore, the design of a spacing between finger gold wires is further optimized. The spacing between the finger gold wires is recalculated using the corrected formula Ls=n*sqrt(Rc/Rs) in the present invention, which can successfully reduce the area shaded by the finger gold wire electrodes to be less than 50%. Through the calculation, it can be seen that compared with the conventional single electrode pad or double electrode pads, the use of the four electrode pads or six electrode pads in the present invention can increase the flux of light output by the chip by 4.3% or more.

As a possible implementation of the present invention, all the electrode pads are axisymmetrically distributed along the periphery of the chip body. Such distribution manner in combination with frame pads distributed on two sides can best ensure a minimum resistance difference between the gold wire and a frame via hole.

As a possible implementation of the present invention, all the electrode pads are symmetrically distributed about an origin point along the periphery of the chip body. Such distribution manner brings about a maximum advantage to the current uniformity. An asymmetric and nonuniform electrode pad distribution likewise brings about a lighting effect improvement, but the lighting effect improvement is not optimal.

It should be noted that, when the chip employs the electrode pads symmetrically and equally spaced apart, the lighting effect improvement ratio is the highest, which can reach 8.5% in a theoretical calculation. Upon actual tests on chips with various electrode pad distributions, it is found that the lighting effect improvement is the highest when the electrode pads are symmetrically distributed about an origin point and equally spaced apart, which is specifically 7.5%. Other distribution modes each achieve a lighting effect improvement of 4% to 6%.

As a possible implementation of the present invention, a proportion of an area shaded by the finger gold wire electrodes in an area of a light emitting region of the chip body is less than 50%, making it possible to effectively maximize the light emitting efficiency of the lamp under a large current of 2000 mA+an extreme operating condition of a high temperature above 85° C.

As a possible implementation of the present invention, by optimizing the design of the distribution of the electrode pads and the spacing between the finger gold wire electrodes, it can be effectively ensured that a ratio of a maximum current to a minimum current on the finger gold wire electrodes is ≤1:1.15, thereby significantly improving the current spreading uniformity of the chip electrode, This avoids concentrating the current in the region near the electrode, which causes a sparse current distribution in the light emitting region on the edge of the chip and leads to the phenomenon of “overcurrent at the origin point and undercurrent on the edge”. The light emitting efficiency is improved, while the problem of intensified local heat generation on the chip due to a nonuniform current distribution is also avoided.

The foregoing LED chip electrode of the present invention is packaged to obtain an LED package. For example, using a four-electrode pad chip for packaging to obtain a package successfully increases a light radiation flux by 3.2% as compared with using a two-electrode pad chip (the chips have totally the same design except for the electrode pads), and reduces the ratio of the maximum current to the minimum current on the finger gold wire electrodes from 1:1.4 to 1:1.15, thereby reducing a forward voltage of the package by approximately 4.2%.

Under a large current of 2000 mA or above and a high-temperature operating condition of 85° C. or above, the light radiation flux is increased by ≥3.2% as compared with the LED chip of the same specification that employs two electrode pads.

In the chip that employs a multi-electrode pad solution, injecting the current from four electrode pads instead of from two electrode pads can greatly reduce a local impact of the large current on the chip. In a double 85° C./85% RH reliability test under a large current of 2.4 A, time to failure is ≥1800 h. A reliability test result of the package is improved from an acceptable level to an excellent level.

In addition, it should be noted that under the same process, using the four electrode pads of the present invention for packaging to obtain a package improves the connection reliability between the chip and the frame by doubling the time as compared with using two electrode pads. An actual thermal shock test result likewise supports the foregoing conclusion, and also reach an excellent level. The number of shocks on the package of the four-electrode pad chip is doubled.

The present invention further provides an LED lighting lamp, including the foregoing LED package, a lamp body housing, and a driving circuit. The driving circuit is configured to provide an operating current of 2000 mA or above to the LED package.

Compared with the prior art, the advantageous effects of the present invention are as follows:
1. By means of the LED chip electrode designed in the present invention, the injection of a large current is effectively dispersed by disposing four or more electrode pads that are symmetrically and equally spaced apart on the periphery of the LED chip. Compared with the conventional single-electrode pad/double-electrode pad solution, it greatly reduces a local impact of the large current on the chip, and can reduce the ratio of the maximum current to the minimum current on the finger gold wire electrodes from 1:1.4 to 1:1.15, thereby effectively improving the current spreading uniformity, and avoiding performance degradation caused by local overcurrent on the chip.
2. The present invention creatively introduces the electrode pad factor n, that is, the number of the electrode pads, which is used to correct and optimize the spacing calculation formula for the finger gold wire electrodes. This can reduce the area shaded by the finger gold wire electrodes to be less than 50%, not only increasing the flux of light output by the package by 4.3%, but also increasing the light radiation flux by ≥3.2% as compared with the conventional double-electrode pad solution. Particularly, when there are four electrode pads symmetrically distributed about the origin point and equally spaced apart, the lighting effect improvement can reach 7.5%, significantly increasing the plant supplementary lighting efficiency.
3. In the present invention, an electrode structure and a current distribution are optimized, so that after the LED chip with the electrode structure in the present invention is packaged into a package, the forward voltage can be reduced by approximately 4.2%, reducing an energy consumption loss while ensuring a high-lighting effect output, which is adapted to an energy saving demand of the large-scale application of the plant supplementary lighting.
4. An 85° C./85% RH test result indicates that under an operating condition of a large current of 2.4 A, the time to failure of the package with the electrode structure in the present invention increases from 1300 h to 1800 h, and a reliability level is improved from an acceptable level to an excellent level. Moreover, the number of shocks in the thermal shock test is doubled, and the connection reliability between the chip and the package frame is improved by one or more times, thereby effectively prolonging the service life of the package and the subsequent lighting lamp, and reducing operation and maintenance costs.
5. The package obtained by packaging the LED chip of the present invention can be directly applied to a plant supplementary lighting LED lamp under a large current and a high-temperature operating condition, satisfying a supplementary lighting demand under an operating current of 2000 mA or above and a high-temperature environment of 85° C. or above, without additional optimization for the structure of the lamp body, which leads to a small modification to an existing lamp manufacturing and production line and a relatively low manufacturing cost.

### BRIEF DESCRIPTION OF THE DRAWINGS

FIG. 1 is a schematic structural diagram of an LED chip electrode according to Embodiment 1 of the present invention;

FIG. 2 is a schematic structural diagram of an LED chip electrode according to Embodiment 2 of the present invention;

FIG. 3 is a schematic structural diagram of an LED chip electrode according to Embodiment 3 of the present invention; and

FIG. 4 is a schematic structural diagram of an LED chip electrode according to Embodiment 4 of the present invention.

Reference numerals are as follows:

1. chip body; 2. electrode pad; and 3. finger gold wire electrode.

### DETAILED DESCRIPTION

Embodiments of the present invention will be described in detail below. Examples of the embodiments are shown in the accompanying drawings, in which the same or similar reference numerals denote the same or similar elements or elements with the same or similar functions throughout. The embodiments described below with reference to the accompanying drawings are illustrative, and are merely intended to explain the present invention, but are not construed as limitations on the present invention.

In the description of the present invention, it should be understood that the orientation or position relationships indicated by the terms “upper”, “lower”, “front”, “rear”, “left”, “right”, “vertical”, “horizontal”, “top”, “bottom”, “inner”, “outer”, and the like are based on the orientation or position relationship shown in the accompanying drawings, and are only for facilitating the description of the present invention and simplifying the description, rather than indicating or implying that an apparatus or an element referred to necessarily have a particular orientation or be constructed and operated in a particular orientation, and therefore will not be interpreted as limitations on the present invention.

In addition, the terms “first” and “second” are merely for the purpose of description, but cannot be construed as indicating or implying relative importance or implicitly indicating the number of indicated technical features. Thus, the features defined with “first” and “second” may explicitly or implicitly include one or more of such features. In the description of the present invention, “a plurality of” means two or more, unless specifically defined otherwise.

In the description of the present invention, unless specified and defined otherwise explicitly, the terms “mounted”, “connected”, “connect”, “fixed”, and the like should be understood in a broad sense. For example, a connection may be a fixed connection, a detachable connection, or an integral connection; may be a mechanical connection or an electrical connection; or may be a direct connection, an indirect connection via an intermediate medium, internal communication between two elements, or an interaction between two elements. A person of ordinary skill in the art may understand the specific meanings of the foregoing terms in the present invention according to specific circumstances.

### Embodiment 1

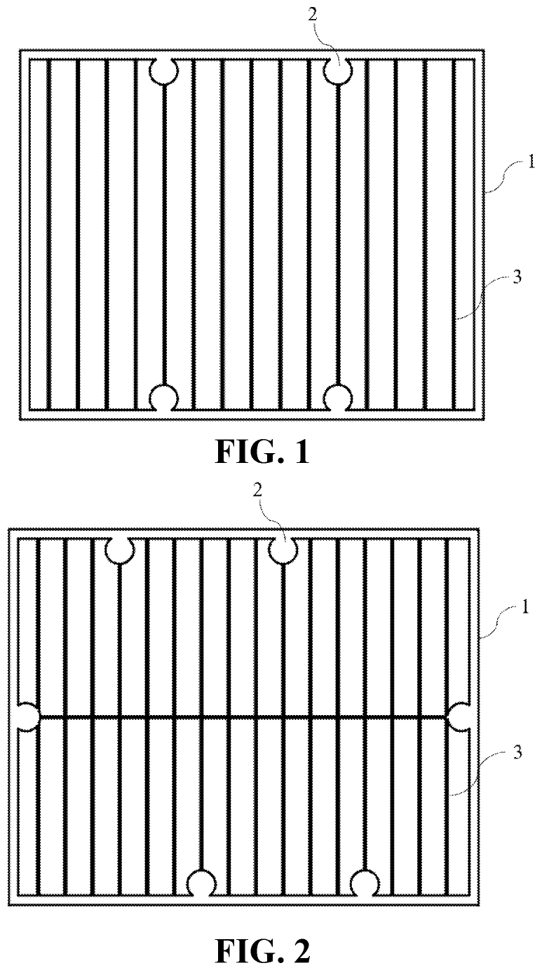

As shown in FIG. 1, this embodiment provides an LED chip electrode. A size of a chip body 1 is 70 mil*70 mil. Four electrode pads 2 are employed. The four electrode pads are axisymmetrically distributed on two sides of the periphery of the chip body 1. Two electrode pads 2 are equally spaced apart on each side. All finger gold wire electrodes 3 are equally spaced apart. A spacing between the finger gold wire electrodes 3 is calculated to be 90 μm.

During packaging, the frame pads are distributed on two sides, so as to best ensure a minimum resistance difference between the gold wire and a frame via hole. Such solution is used for packaging to obtain a package. A control group is set. The control group differs from Embodiment 1 in that the control group employs two electrode pads. Under the conditions of the same package process, the same forward voltage of the chip, and the same light radiation flux of the chip, compared with data regarding the number of times for a package of a two-electrode pad chip in the control group, the lighting effect is improved from 3.67 μmol/J at 85° C. and 1800 mA to 3.946 μmol/J at 85° C. and 1800 mA. The lighting effect of the package is improved by 7.5%, where the contribution of a VF value of the package is reduced by 4.6%, and a light radiation flux of the package is increased by 2.9%.

### Embodiment 2

As shown in FIG. 2, this embodiment provides an LED chip electrode. A size of a chip body 1 is 70 mil*70 mil. Six electrode pads 2 are employed, where four electrode pads 2 are symmetrically distributed about an origin point on two sides of the periphery of the chip body 1, two electrode pads 2 are located at origin points of the other two sides of the periphery of the chip body 1, and a finger gold wire electrode 3 is connected between the two electrode pads 2. All finger gold wire electrodes 3 are equally spaced apart. A spacing between the finger gold wire electrodes 3 is calculated to be 109 μm.

During packaging, frame pads are distributed on four sides. Such solution is used for packaging to obtain a package. In comparison with the control group in Embodiment 1, under the conditions of the same package process, the same forward voltage of the chip, and the same light radiation flux of the chip, compared with data regarding the number of times for a package of a two-electrode pad chip in the control group, the lighting effect is improved from 3.67 μmol/J at 85° C. and 1800 mA to 3.93 μmol/J at 85° C. and 1800 mA. The lighting effect of the package is improved by 7.1%, where the contribution of a VF value of the package is reduced by 4.5%, and a light radiation flux of the package is increased by 2.6%.

### Embodiment 3

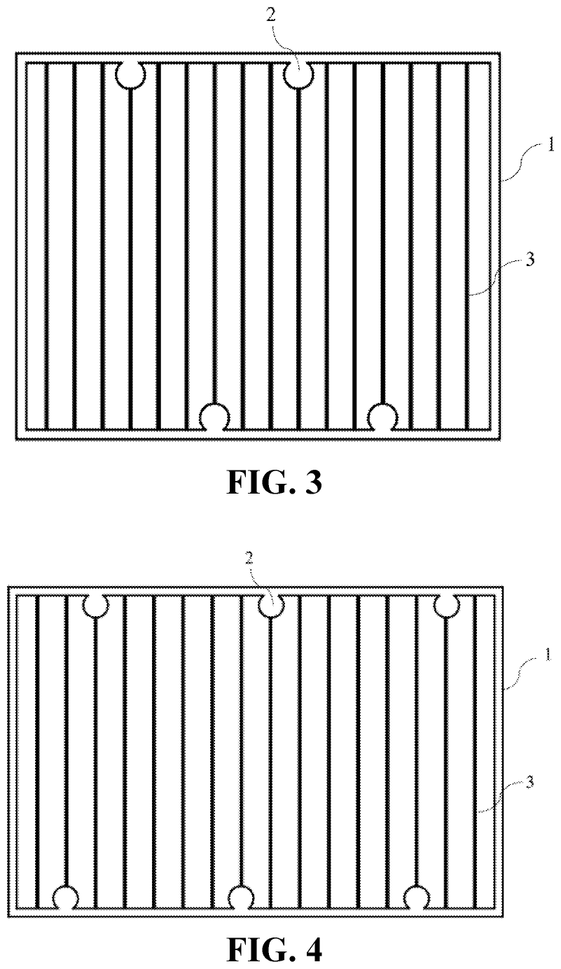

As shown in FIG. 3, this embodiment provides an LED chip electrode. A size of a chip body 1 is 70 mil*70 mil. Four electrode pads 2 are employed. The four electrode pads 2 are symmetrically distributed about an origin point on two sides of the periphery of the chip body 1. Two electrode pads 2 are equally spaced apart on each side. All finger gold wire electrodes 3 are equally spaced apart. A spacing between the finger gold wire electrodes 3 is calculated to be 90 μm.

During packaging, frame pads are distributed on two sides. Such solution is used for packaging to obtain a package. In comparison with the control group in Embodiment 1, under the conditions of the same package process, the same forward voltage of the chip, and the same light radiation flux of the chip, compared with data regarding the number of times for a package of a two-electrode pad chip in the control group, the lighting effect is improved from 3.66 μmol/J at 85° C. and 1800 mA to 3.872 μmol/J at 85° C. and 1800 mA. The lighting effect of the package is improved by 5.8%, where the contribution of a VF value of the package is reduced by 3.2%, and a light radiation flux of the package is increased by 2.6%.

### Embodiment 4

As shown in FIG. 4, this embodiment provides an LED chip electrode. A size of a chip body 1 is 65 mil*75 mil. Six electrode pads 2 are employed, where the six electrode pads 2 are symmetrically distributed about an origin point on two sides of the periphery of the chip body 1, with three electrode pads 2 equally spaced apart disposed on each side. All finger gold wire electrodes 3 are equally spaced apart. A spacing between the finger gold wire electrodes 3 is calculated to be 109 μm.

During packaging, frame pads are distributed on two sides. Such solution is used for packaging to obtain a package. In comparison with the control group in Embodiment 1, under the conditions of the same package process, the same forward voltage of the chip, and the same light radiation flux of the chip, compared with data regarding the number of times for a package of a two-electrode pad chip in the control group, the lighting effect is improved from 3.66 μmol/J at 85° C. and 1800 mA to 3.92 μmol/J at 85° C. and 1800 mA. The lighting effect of the package is improved by 7.1%, where the contribution of a VF value of the package is reduced by 4%, and a light radiation flux of the package is increased by 3.1%.

The present invention and implementations thereof are described above in an illustrative way, and the description is not limitative. The accompanying drawings show only one of the implementations of the present invention, and an actual structure is not limited thereto. Therefore, if a person of ordinary skill in the art is inspired hereby to design a structural manner and an embodiment similar to the technical solution without creative designs and without departing from the spirit of the present invention, they shall fall within the protection scope of the present invention.

What is claimed is:

1. An LED chip electrode, comprising a chip body (1), electrode pads (2) disposed on the periphery of the chip body (1), and finger gold wire electrodes (3) disposed on a surface of the chip body (1), wherein
four or more electrode pads (2) are provided, and are symmetrically and equally spaced apart along the periphery of the chip body (1);
the finger gold wire electrodes (3) are equally spaced apart, and the spacing between two adjacent ones of the finger gold wire electrodes (3) is determined according to the following formula:
Lₛ=n*sqrt(R_{c}/Rₛ)
wherein Lₛ is the spacing between two adjacent ones of the finger gold wire electrodes (3), n is the number of the electrode pads (2), R_{c} is a contact resistance between the finger gold wire electrodes (3) and the chip body (1), and Rₛ is a sheet resistance of the chip body (1).

2. The LED chip electrode according to claim 1, wherein the number of the electrode pads (2) is four or six.

3. The LED chip electrode according to claim 2, wherein all the electrode pads (2) are axisymmetrically distributed along the periphery of the chip body (1).

4. The LED chip electrode according to claim 2, wherein all the electrode pads (2) are symmetrically distributed about an origin point along the periphery of the chip body (1).

5. The LED chip electrode according to claim 1, wherein the proportion of the area shaded by the finger gold wire electrodes (3) in the area of a light emitting region of the chip body (1) is less than 50%.

6. The LED chip electrode according to claim 2, wherein the proportion of the area shaded by the finger gold wire electrodes (3) in the area of a light emitting region of the chip body (1) is less than 50%.

7. The LED chip electrode according to claim 1, wherein the ratio of the maximum current to the minimum current on the finger gold wire electrodes (3) is ≤1:1.15.

8. The LED chip electrode according to claim 2, wherein the ratio of the maximum current to the minimum current on the finger gold wire electrodes (3) is ≤1:1.15.

9. The LED chip electrode according to claim 1, wherein under a large current of 2000 mA or above and a high-temperature operating condition of 85° C. or above, a light radiation flux is increased by ≥3.2% as compared with an LED chip of the same specification that employs two electrode pads.

10. The LED chip electrode according to claim 2, wherein under a large current of 2000 mA or above and a high-temperature operating condition of 85° C. or above, a light radiation flux is increased by ≥3.2% as compared with an LED chip of the same specification that employs two electrode pads.

11. The LED chip electrode according to claim 3, wherein under a large current of 2000 mA or above and a high-temperature operating condition of 85° C. or above, a light radiation flux is increased by ≥3.2% as compared with an LED chip of the same specification that employs two electrode pads.

12. The LED chip electrode according to claim 4, wherein under a large current of 2000 mA or above and a high-temperature operating condition of 85° C. or above, a light radiation flux is increased by ≥3.2% as compared with an LED chip of the same specification that employs two electrode pads.

13. The LED chip electrode according to claim 1, wherein in an 85° C./85% RH reliability test under a large current of 2.4 A, time to failure is ≥1800 h.

14. The LED chip electrode according to claim 2, wherein in an 85° C./85% RH reliability test under a large current of 2.4 A, time to failure is ≥1800 h.

15. The LED chip electrode according to claim 3, wherein in an 85° C./85% RH reliability test under a large current of 2.4 A, time to failure is ≥1800 h.

16. The LED chip electrode according to claim 4, wherein in an 85° C./85% RH reliability test under a large current of 2.4 A, time to failure is ≥1800 h.
